(19) United States
(12) Patent Application Publication
(10) Pub. No.: US 2013/0017690 A1
(43) Pub. Date: Jan. 17, 2013

(54) PLASMA NITRIDING METHOD AND PLASMA NITRIDING APPARATUS

(71) Applicants: Koichi Takatsuki, Yamanashi (JP); Kazuyoshi Yamazaki, Yamanashi (JP); Hideyuki Noguchi, Yamanashi (JP); Daisuke Tamura, Yamanashi (JP); Tomohiro Saito, Yamanashi (JP)

(72) Inventors: Koichi Takatsuki, Yamanashi (JP); Kazuyoshi Yamazaki, Yamanashi (JP); Hideyuki Noguchi, Yamanashi (JP); Daisuke Tamura, Yamanashi (JP); Tomohiro Saito, Yamanashi (JP)

(73) Assignee: TOKYO ELECTRON LIMITED, Tokyo (JP)

(21) Appl. No.: 13/638,284

(22) PCT Filed: Mar. 30, 2011
(86) PCT No.: PCT/JP11/57958

§ 371 Date: Sep. 28, 2012

(30) Foreign Application Priority Data
Mar. 31, 2010 (JP) 2010-081989

(51) Int. Cl. C23C 16/511; H01L 21/314

(52) U.S. Cl. 438/786; 118/723 AN; 257/E21.267

(57) ABSTRACT

In a plasma nitriding method, a processing gas containing nitrogen gas and rare gas is introduced into a processing chamber of a plasma processing apparatus by setting a flow rate thereof as a total flow rate [mL/min(sccm)] of the processing gas per 1 L volume of the processing chamber within a range from 1.5 (mL/min)/L to 13 (mL/min)/L. Further, a nitriding process is performed on oxygen-containing films of target objects to be processed by generating a nitrogen-containing plasma in the processing chamber and while exchanging the target objects.

### FIELD OF THE INVENTION

The present invention relates to a plasma nitriding method and a plasma nitriding apparatus.

### BACKGROUND OF THE INVENTION

A plasma processing apparatus for performing a process such as film formation or the like by using a plasma is employed in a manufacturing process of various semiconductor devices fabricated on, e.g., a silicon semiconductor or a compound semiconductor, a FPD (Flat Panel Display) represented by a liquid crystal display (LCD), and the like. In this plasma processing apparatus, a component made of a dielectric material such as quartz or the like is widely used as a component in the processing chamber. For example, there is known a microwave-excited plasma processing apparatus for generating a plasma by introducing a microwave into a processing chamber through a planar antenna having a plurality of slots. This microwave-excited plasma processing apparatus is configured to generate a high-density plasma by reacting a processing gas with a microwave transmitted to a planar antenna and introduced into a space in the processing chamber through a microwave transmitting plate made of quartz (also referred to as a ceiling plate or a transmitting plate) (see, e.g., Japanese Patent Application Publication No. 2008-34579 (FIG. 1 etc.)).

Meanwhile, when various semiconductor devices or products such as a FPD and the like are manufactured, allowable inter-surface uniformity (uniformity between substrates) of a processing result and a reference value of the number of particles (allowable number of particles) have been set for product management. Therefore, it is very important to increase the inter-surface uniformity of the processing result and reduce the number of particles in order to improve the production yield.

Here, “inter-surface uniformity of the processing result” denotes that deviations in a thickness of a nitride film, a nitrogen dose or the like among a plurality of substrates serving as target objects to be processed are within a specific range, for example, in a plasma nitriding process for nitriding silicon on surfaces of the target objects by using the same plasma processing apparatus. While, however, the plasma nitriding process is being repeatedly performed on the target objects by using any plasma processing apparatus, the inter-uniformity of the nitrogen dose may be deteriorated and the number of particles generated from the plasma processing apparatus may excess the reference value.

### SUMMARY OF THE INVENTION

In view of the above, the present invention provides a plasma nitriding method capable of suppressing generation of particles from a processing apparatus while ensuring inter-surface uniformity of a nitrogen dose even when a plasma nitriding process is continuously performed on a plurality of target objects to be processed in a same processing chamber.

The present inventors have investigated the reason for the increase of the number of particles generated in the processing chamber and the decrease of the inter-plane uniformity during the repetitive performance of the plasma nitriding process on the target objects in the plasma processing apparatus. As a result, they have found that surface states of components (e.g., quartz members and the like) in the plasma processing apparatus are changed in accordance with the processing conditions and this affects the generation of particles and the decrease of the inter-plane uniformity. An embodiment of the present invention has been conceived based on such conclusion.

In accordance with an aspect of the present invention, there is provided a plasma nitriding method including introducing a processing gas containing nitrogen gas and rare gas to a processing chamber of a plasma processing apparatus by setting a flow rate thereof as a total flow rate [mL/min(sccm)] of the processing gas per 1 L volume of the processing chamber within a range from 1.5 (mL/min)/L to 13 (mL/min)/L; and performing a nitriding process on a plurality of oxygen-containing films of target objects to be processed by generating a nitrogen-containing plasma in the processing chamber and while exchanging the target objects.

A volume flow rate ratio (nitrogen gas/rare gas) of the nitrogen gas and the rare gas may be set within a range from about 0.05 to 0.8. In this case, the flow rate of the nitrogen gas may be set within a range from about 4.7 mL/min(sccm) to 225 mL/min(sccm), and the flow rate of the rare gas may be set within a range from about 95 mL/min(sccm) to 275 mL/min(sccm).

A pressure in the processing chamber may be set within a range from about 1.3 Pa to 133 Pa.

A processing time for one target object in the plasma nitriding process may be set within a range from about 10 sec to 300 sec.

The plasma processing apparatus may includes: the processing chamber having an upper opening; a mounting table, provided in the processing chamber, for mounting thereon the target object; a transmitting plate provided to face the mounting table, the transmitting plate covering the opening of the processing chamber and transmitting a microwave; a planar antenna provided outside the transmitting plate, the planar antenna having a plurality of slots through which the microwave is introduced into the processing chamber; a gas inlet for introducing the processing gas containing nitrogen gas and rare gas from a gas supply unit into the processing chamber; and a gas exhaust unit for vacuum-evacuating the processing chamber, wherein the nitrogen plasma is a microwave-excited plasma formed by the processing gas and a microwave introduced into the processing chamber through the planar antenna

A power density of the microwave may be set in a range from about 0.6 W/cm² to 2.5 W/cm² per area of the transmitting plate.

The processing temperature may be a temperature of the mounting table and may be set within a range from about 25° C. (room temperature) to about 600° C.

In accordance with another aspect of the present invention, there is provided a plasma nitriding apparatus including a processing chamber having an upper opening; a mounting table, provided in the processing chamber, for mounting thereon a target object to be processed; a transmitting plate provided to face the mounting table, the transmitting plate covering the opening of the processing chamber and transmitting a microwave; a planar antenna, provided outside the transmitting plate, the planar antenna having a plurality of slots through which the microwave is introduced into the processing chamber; a gas inlet for introducing a processing gas containing nitrogen gas and rare gas from a gas supply unit into the processing chamber; a gas exhaust unit for vacuum-evacuating the processing chamber; and a control unit for controlling a plasma nitriding process to be performed on the target object in the processing chamber, wherein the control unit performs the steps of: lowering a pressure in the processing chamber to a predetermined level by exhausting the processing chamber by the gas exhaust unit; introducing the processing gas containing nitrogen gas and rare gas from the gas supply unit into the processing chamber through the gas inlet by setting a flow rate thereof as a total flow rate [mL/min(sccm)] of the processing gas per 1 L volume of the processing chamber within a range from 1.5 (mL/min)/L to 13 (mL/min)/L, the flow rate being the; generating a nitrogen-containing plasma in the processing chamber by introducing the microwave into the processing chamber through the planar antenna and the transmitting plate; and nitriding an oxygen-containing film of the target object by using the nitrogen-containing plasma.

In the plasma nitriding method in accordance with the aspects of the present invention, the processing gas containing a nitrogen gas and a rare gas is introduced into the processing chamber at a total flow rate in a range from about 1.5 (mL/min)/L or 13 (mL/min)/L. Hence, the processing uniformity among the target objects (inter-surface uniformity) can be improved, and the generation of particles in the processing chamber can be efficiently suppressed by preventing oxidation of the quartz member in the processing chamber. By setting the total flow rate to the above range, the variations of the nitrogen dose which are caused by the memory effect among different types of wafers can be suppressed. Accordingly, it is possible to realize the plasma nitriding process in which a small number of particles are generated and high reliability is ensured.

### BRIEF DESCRIPTION OF THE DRAWINGS

FIG. 1 is a schematic cross-sectional view showing a configuration example of a plasma-nitriding apparatus suitable for implementation of a plasma-nitriding method in accordance with the present invention;

FIG. 2 shows a configuration of a planar antenna;

FIG. 3 explains a configuration of a control unit;

FIG. 4 explains a surface change of a quartz member in a plasma nitriding process;

FIG. 5 explains a surface state of the quartz member which is continued from FIG. 4;

FIG. 6 explains a surface state of the quartz member which is continued from FIG. 5;

FIG. 7 explains a surface state of the quartz member which is continued from FIG. 6;

FIG. 8 shows a result on a nitrogen dose of a silicon nitride film formed under a small flow rate condition 1-A of a test example 1 and a result of uniformity among wafers;

FIG. 9 shows a result on a nitrogen dose of a silicon nitride film formed under a large flow rate condition 1-B of the test example 1 and a result of uniformity among wafers;

FIG. 10 shows a result on a nitrogen dose of a silicon nitride film formed under a large flow rate condition 1-C of the test example 1 and a result of uniformity among wafers;

FIG. 11 shows relationship between the number of particles and the number of processed wafers in a test example 2;

FIG. 12 shows a nitrogen dose of a silicon nitride film formed in a test example 3 and intra-wafer surface uniformity;

FIG. 13 compares states of a transmitting plate before and after plasma nitriding processes performed under a small flow rate condition and a large flow rate condition in a test example 4;

FIG. 14 is a graph showing a measurement result of contamination on a top surface of a wafer before and after plasma conditioning performed based on a first recipe;

FIG. 15 is a graph showing a measurement result of contamination on a bottom surface of a wafer before and after plasma conditioning performed based on the first recipe;

FIG. 16 is a graph showing a measurement result of contamination on a top surface of a wafer after plasma conditioning performed based on a second recipe;

FIG. 17 is a graph showing a measurement result of contamination on a bottom surface of the wafer before and after the plasma conditioning performed based on the second recipe; and

FIG. 18 is a graph showing measurement results of contamination on a top surface and a bottom surface of a wafer after plasma conditioning performed based on a third recipe.

### DETAILED DESCRIPTION OF THE EMBODIMENTS

Hereinafter, a plasma nitriding method in accordance with an embodiment of the present invention will be described in detail with reference to the accompanying drawings.

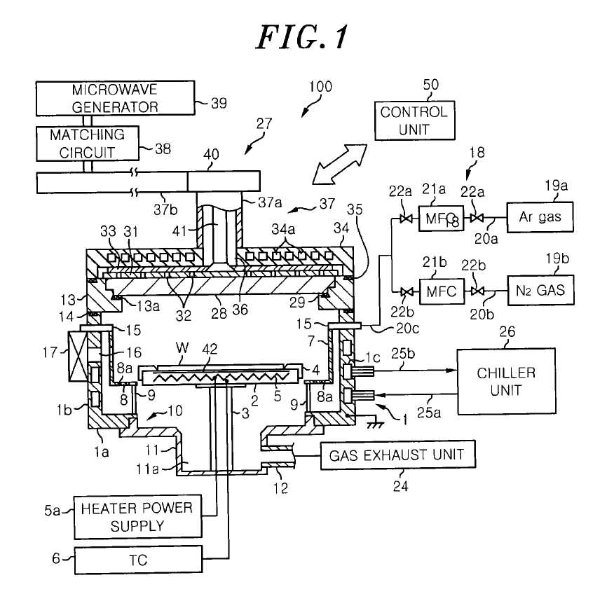

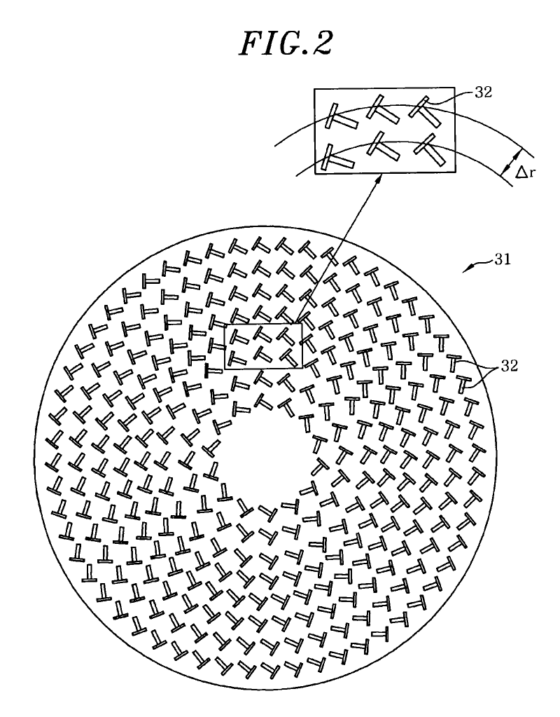

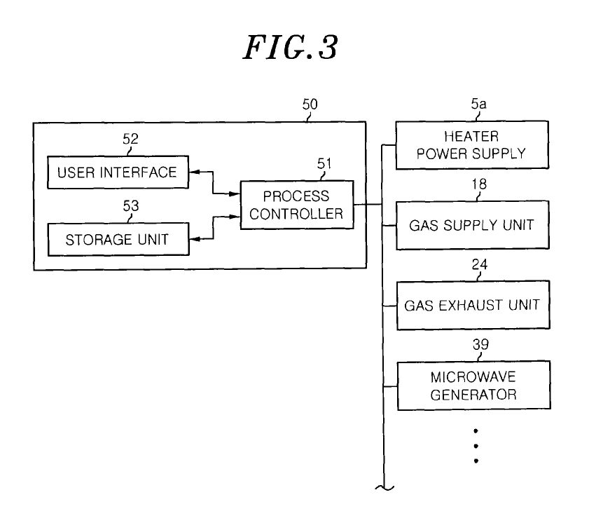

First, a configuration of a plasma-nitriding apparatus that may be used in a plasma-nitriding method in accordance with the embodiment of the present invention will be described with reference to FIGS. 1 to 3. FIG. 1 is a cross-sectional view schematically showing a configuration of the plasma-nitriding apparatus 100. FIG. 2 is a plan view showing a planar antenna of the plasma-nitriding apparatus 100 shown in FIG. 1. FIG. 3 shows a configuration of a control system of the plasma-nitriding apparatus 100.

The plasma-nitriding apparatus 100 is configured as a RLSA (Radial Line Slot Antenna) microwave plasma processing apparatus capable of generating a plasma in a processing chamber by introducing a microwave into the processing chamber through a planar antenna, particularly, a RLSA, having a plurality of slot-shaped holes. Thus, in the plasma nitriding apparatus 100, a microwave-excited plasma can be generated with a high density and a low electron temperature. Further, in the plasma nitriding apparatus 100, a process can be performed by a plasma with a plasma density in a range from 1×10¹⁰ to 5×10¹²/cm³ and a low electron temperature in a range from about 0.7 to 2 eV. Accordingly, the plasma-nitriding apparatus 100 can be suitably used for the purpose of forming, e.g., a silicon oxynitride film (SiON film) or a silicon nitride film (SiN film) by nitriding a silicon oxide film or silicon in a manufacturing process of various semiconductor devices.

The plasma-nitriding apparatus 100 includes, as main elements, a processing chamber 1 for accommodating therein a semiconductor wafer W (hereinafter, simply referred to as “wafer”) serving as a target object to be processed; a mounting table 2 for mounting thereon the wafer W in the processing chamber 1; a gas inlet 15 connected to a gas supply unit 18 for introducing a gas into the processing chamber 1; a gas exhaust unit 24 for vacuum-evacuating the processing chamber 1; an microwave introducing unit 27, provided at an upper portion of the processing chamber 1, serving as a plasma generation unit for generating a plasma by introducing a microwave into the processing chamber 1; and a control unit 50 for controlling various components of the plasma-nitriding apparatus 100. The term “target object to be processed (wafer W)” used herein includes various films formed on a surface thereof, e.g., a polysilicon layer, a silicon dioxide film and the like. The gas supply unit 18 may be included in the plasma nitriding apparatus 100. The gas supply unit may be connected as an external unit to the gas inlet 15 instead of being included in the plasma nitriding apparatus 100.

The processing chamber 1 is formed in an approximately cylindrical shape, which is grounded. The volume of the processing chamber 1 can be properly controlled. In the present embodiment, the processing chamber 1 has a volume of, e.g., about 55 L. Alternatively, the processing chamber 1 may be formed in a square tubular shape. The processing chamber 1 has an opening at an upper portion thereof, and also has a bottom wall 1a and a sidewall 1b made of aluminum or the like. A heat medium flow path 1c is formed in the sidewall 1b.

A mounting table 2 for horizontally supporting a wafer W as a target object to be processed is provided in the processing chamber 1. The mounting table 2 is formed of ceramic such as AlN, Al₂O₃ or the like. Among them, particularly, a material with a high thermal conductivity, e.g., AlN, is preferably used. The mounting table 2 is supported by a cylindrical support member 3 extending upwardly from a central bottom portion of a gas exhaust chamber 11. The support member 3 is made of, e.g., ceramic such as AlN or the like.

Further, a cover member 4 is provided in the mounting table 2 to cover an outer peripheral portion of the mounting table 2 and guide the wafer W. The cover ring 4 is formed in an annular shape to cover a mounting surface and/or a side surface of the mounting table 2. The presence of the cover member 4 makes it possible to suppress the plasma from being in contact with the mounting table 2 and prevent the mounting table 2 from being sputtered. Also, it is possible to prevent the diffusion of impurities into the wafer W.

The cover member 4 is made of a material, e.g., quartz, single crystalline silicon, poly silicon, amorphous silicon, silicon nitride or the like. Among them, quartz having a good compatibility with the plasma is most preferably used. In addition, the material of the cover member 4 is preferably made of a high-purity material, such as alkali metal, metal or the like, having low concentration of impurities.

Further, a resistance heater 5 is embedded in the mounting table 2. The heater 5 is powered from a heater power supply 5a to heat the mounting table 2, thereby uniformly heating the wafer W as the target object.

A thermocouple (TC) 6 is also provided in the mounting table 2. The temperature of the mounting table 2 is measured by the thermocouple 6, so that the heating temperature of the wafer W can be controlled in a range from a room temperature to 900° C.

Further, there are provided in the mounting table 2 wafer support pins (not shown) that are used for exchanging wafers W when a wafer W is loaded into the processing chamber 1. Each of the wafer support pins is provided to protrude from and retreat below the top surface of the mounting table 2.

A cylindrical liner 7 made of quartz is provided on an inner periphery of the processing chamber 1. Further, an annular baffle plate 8 made of quartz is provided on an outer peripheral side of the mounting table 2 to uniformly evacuate the processing chamber 1. The baffle plate 8 has a plurality of gas exhaust holes 8a and is supported by support columns 9.

A circular opening 10 is formed in an approximately central portion of the bottom wall 1a of the processing chamber 1. The exhaust chamber 11 is provided in the bottom wall 1a to protrude downward and communicate with the opening 10. A gas exhaust pipe 12 is connected to the gas exhaust chamber 11, and is connected to the gas exhaust unit 24. In this way, the processing chamber 1 is configured to be vacuum-evacuated.

The processing chamber 1 has an upper opening. Provided at the upper opening of the processing chamber 1 is a frame-shape plate 13 that has a function (lid function) of opening and closing the processing chamber 1. An inner periphery of the frame-shaped plate 13 serves as an annular support portion 13a protruding inwardly (toward the inner space of the processing chamber). A gap between the support portion 13a and the processing chamber 1 is airtightly sealed by a sealing member 14.

Provided in the sidewall 1b of the processing chamber 1 are a loading/unloading port 16 through which the wafer W is loaded/unloaded between the plasma-nitriding apparatus 100 and a transfer chamber (not shown) adjacent to the plasma-nitriding apparatus 100, and a gate valve 17 for opening and closing the loading/unloading port 16.

The annular gas inlet 15 has an annual shape and is provided at the sidewall 1b of the processing chamber 1. The gas inlet 15 is connected to the gas supply unit 18 for supplying a rare gas or nitrogen gas. Further, the gas inlet 15 may be formed in a nozzle shape or a shower shape.

The gas supply unit 18 includes gas supply sources; lines (e.g., gas lines 20a to 20c); flow rate controllers (e.g., mass flow controllers 21a and 21b); and valves (e.g., opening/closing valves 22a and 22b). The gas supply sources include, e.g., a rare gas supply source 19a and a nitrogen gas supply source 19b. Further, the gas supply unit 18 may further include, as a gas supply source (not shown) other than the above-described gas supply sources, e.g., a purge gas supply source or the like used when changing the atmosphere in the processing chamber 1.

In FIG. 1, Ar gas is supplied from the rare gas supply source 19a. In addition, Kr gas, Xe gas, He gas or the like may be used as the rare gas. Among them, particularly, Ar gas is preferably used in view of economical efficiency.

The rare gas and the nitrogen gas are respectively supplied from the rare gas supply source 19a and the nitrogen gas supply source 19b of the gas supply unit 18 through the gas lines 20a and 20b. The gas lines 20a and 20b are joined at the gas line 20c, and the gases are introduced into the processing chamber 1 through the gas inlet 15 connected to the gas line 20c. The gas lines 20a and 20b are reactively connected to the gas supply sources are provided with mass flow controllers 21a and 21b and pairs of opening/closing valves 22a and 22b disposed at an upstream side and a downstream side thereof. By such a configuration of the gas supply unit 18, it is possible to switch the supplied gases or control a flow rate of the supplied gases.

The exhaust unit 24 includes a high-speed vacuum pump, e.g., a turbo molecular pump or the like. As described above, the gas exhaust unit 24 is connected to the exhaust chamber 11 of the processing chamber 1 through the gas exhaust line 12. The gas in the processing chamber 1 uniformly flows in a space 11a of the exhaust chamber 11, and the gas is exhausted from the space 11a through the exhaust pipe 12 by operating the gas exhaust unit 24. Accordingly, an internal pressure of the processing chamber 1 can be rapidly reduced to a predetermined vacuum level of, e.g., 0.133 Pa.

The heat medium flow path 1c is formed in the sidewall 1b of the processing chamber 1. The heat medium flow path 1c is connected to a chiller unit 26 through a heat medium inlet line 25a and a heat medium outlet line 25b. The chiller unit 26 circulates a heat medium controlled to a predetermined temperature in the heat medium flow path 1c, thereby controlling the temperature of the sidewall 1b of the processing chamber 1.

Next, a configuration of the microwave introducing unit 27 will be described. The microwave introducing unit 27 includes, as main elements, a transmitting plate 28; a planar antenna 31; a wave-retardation member 33; a cover member 34 made of metal; a waveguide 37; a matching circuit 38 and a microwave generator 39. The microwave introducing unit 27 serves as a plasma generator for generating a plasma by introducing an electromagnetic wave (microwave) into the processing chamber 1.

The transmitting plate 28, which serves to transmit a microwave, is disposed on the support portion 13a protruding inward in the plate 13. The transmitting plate 28 is made of a dielectric material, e.g., quartz or the like. A seal member 29 such as an O-ring or the like is provided to airtightly seal a gap between the transmitting plate 28 and the support portion 13a, thereby maintaining airtightness of the processing chamber 1

The planar antenna 31 is disposed on the transmitting plate 28 (outside the processing chamber 1) to correspond to the mounting table 2. The planar antenna 31 has a disc shape. Alternatively, the planar antenna 31 may have, e.g., a rectangular plate shape without being limited to a disc shape. The planar antenna 31 is engaged with an upper end of the lid member 13.

The planar antenna 31 is formed of a conductive member, e.g., a copper plate, an aluminum plate, a nickel plate, or a plate of an alloy thereof, which is plated with gold or silver. The planar antenna 31 has a plurality of slot-shaped microwave radiation holes 32 through which the microwave is radiated. The microwave radiation holes 32 are formed in a predetermined pattern to extend through the planar antenna 31.

Each of the microwave radiation holes 32 has, e.g., an elongated rectangular shape (slot shape) as shown in FIG. 2. Further, generally, the adjacent microwave radiation holes 32 are arranged in an “L” shape. The microwave radiation holes 32 which are combined in groups in a specific shape (e.g., L shape) are wholly arranged in a concentric circular pattern.

A length and an arrangement interval of the microwave radiation holes 32 are determined based on the wavelength (λg) of the microwave. For example, the microwave radiation holes 32 are arranged at the arrangement interval ranging from λg/4 to λg. In FIG. 2, the arrangement interval between the adjacent microwave radiation holes 32 formed in the concentric circular pattern is represented as Δr. The microwave radiation holes 32 may have another shape such as a circular shape or a circular arc shape. Moreover, the microwave radiation holes 32 may be arranged in another pattern, e.g., a spiral or a radial pattern, without being limited to the concentric circular pattern.

The wave-retardation member 33 having a larger dielectric constant than that of the vacuum is disposed on an upper surface of the planar antenna 31 (a flat waveguide formed between the planar antenna 31 and the cover member 34). Since the microwave has a longer wavelength in the vacuum, the wave-retardation member 33 functions to shorten the wavelength of the microwave to control the plasma. For example, quartz, polytetrafluoroethylene resin, polyimide resin or the like may be used as the material of the wave-retardation member 33.

The planar antenna 31 may be in contact with or separated from the transmitting plate 28, but it is preferable that the planar antenna 31 is in contact with the microwave transmitting plate 28. Moreover, the wave-retardation member 33 may be in contact with or separated from the planar antenna 31, but it is preferable that the wave-retardation member 33 is in contact with the planar antenna 31.

The cover member 34 is provided at the top of the processing chamber 1 to cover the planar antenna 31 and the wave-retardation member 33. The cover member 34 is made of a metal material such as aluminum, stainless steel or the like. A flat waveguide is constituted by the cover member and the planar antenna 31, so that the microwave is supplied uniformly into the processing chamber 1. A seal member 35 is provided to seal a gap between an upper end of the plate 13 and the metal cover member 34. Further, the cover member 34 has a passage 34a formed therein. The passage 34a is connected to the chiller unit 26 through a line (not shown). The metal cover member 34, the wave-retardation member 33, the planar antenna 31 and the transmitting plate 28 may be cooled by flowing a heat medium such as a cooling water or the like from the chiller unit 36 through the passage 34a. Moreover, the metal cover member 34 is grounded.

An opening 36 is formed in a central portion of an upper wall (ceiling) of the cover member 34. The opening 36 is connected to one end of the waveguide 37. The microwave generator 39 for generating a microwave is connected to the other end of the waveguide 37 via the matching circuit 38. The waveguide 37 includes a coaxial waveguide 37a having a circular cross sectional shape and extending upward from the opening 36 of the cover member 34; and a rectangular waveguide 37b connected to an upper end of the coaxial waveguide 37a via a mode transducer 40 and extended in a horizontal direction. The mode transducer 40 functions to convert a microwave propagating in a TE mode in the rectangular waveguide 37b into a TEM mode microwave.

An internal conductor 41 extends through the center of the coaxial waveguide 37a. A lower end of the internal conductor 41 is connected and fixed to a central portion of the planar antenna 31. With this structure, the microwave is efficiently, uniformly and radially propagated to the flat waveguide constituted by the metal cover member 34 and the planar antenna 31 through the internal conductor 41 of the coaxial waveguide 37a.

By the microwave introducing unit 27 having the above configuration, the microwave generated in the microwave generator 39 is propagated to the planar antenna 31 through the waveguide 37, and then introduced into the processing chamber 1 through the microwave radiation holes 32 (slots) and the transmitting plate 28. The microwave preferably has a frequency of, e.g., 2.45 GHz, but the frequency of the microwave may be 8.35 GHz, 1.98 GHz or the like.

Each component of the plasma-nitriding apparatus 100 is connected to and controlled by the control unit 50. The control unit 50 is typically a computer. For example, as shown in FIG. 3, the control unit 50 includes a process controller 51 having a CPU; and a user interface 52 and a storage unit 53, which are connected to the process controller 51. The process controller 51 serves as a control unit for integratedly controlling, in the plasma nitriding apparatus 100, the respective components (e.g., the heater power supply 5a, the gas supply unit 18, the exhaust unit 24, the microwave generator 39 and the like) which are associated with the processing conditions such as temperature, pressure, gas flow rate, microwave output and the like.

The user interface 52 includes a keyboard through which a process operator performs, e.g., an input operation in accordance with commands in order to manage the plasma-nitriding apparatus 100; a display for visually displaying an operational status of the plasma-nitriding apparatus 100; and the like. Further, the storage unit 53 stores a recipe including process condition data or control programs (software) for performing various processes in the plasma-nitriding apparatus 100 under the control of the process controller 51.

Further, if necessary, a certain recipe is retrieved from the storage unit 53 in accordance with instructions inputted through the user interface 52 and executed by the process controller 51. Accordingly, a desired process is performed in the processing chamber 1 of the plasma-nitriding apparatus 100 under the control of the process controller 51. The recipe including process condition data or control programs may be stored in a computer-readable storage medium, e.g., CD-ROM, hard disk, flexible disk, flash memory, DVD, blue-ray disc and the like. Alternatively, the recipe may be transmitted at any time from a separate device through, e.g., a dedicated line.

In the plasma-nitriding apparatus 100 having the above configuration, a plasma process can be performed at a low temperature ranging between about 25° C. (about a room temperature) and 600° C. without causing damage to the wafer W. Further, since the plasma-nitriding apparatus 100 has an excellent plasma uniformity, in-plane uniformity and inter-surface uniformity of processing may be achieved even on a large-sized wafer W.

The following description relates to an example of the general sequence of a plasma nitriding process performed by using the RLSA-type plasma nitriding apparatus 100. First, a wafer W is loaded into the processing chamber 1 through the loading/unloading port 16 by opening the gate valve 17, and then mounted on the mounting table 2. Next, a rare gas and a nitrogen gas are respectively introduced into the processing chamber 1 at predetermined flow rates from the rare gas supply source 19a and the nitrogen gas supply source 19b of the gas supply unit 18 through the gas inlet 15 while the processing chamber 1 is uniformly evacuated. In this manner, the internal pressure of the processing chamber 1 is adjusted to a predetermined level. Moreover, the sidewall 1b of the processing chamber 1 is controlled to a predetermined temperature by circulating a heat medium of a predetermined temperature in the heat medium flow path 1c by the chiller unit 26.

Then, the microwave of a predetermined frequency, e.g., 2.45 GHz, generated from the microwave generator 39 is transmitted to the waveguide 37 via the matching circuit 38. The microwave transmitted to the waveguide 37 sequentially passes through the rectangular waveguide 37b and the coaxial waveguide 37a, and is supplied to the planar antenna 31 through the internal conductor 41. The microwave propagates in a TE mode in the rectangular waveguide 37b, and the TE mode microwave is converted into a TEM mode microwave by the mode convertor 40. The TEM mode microwave propagates in the coaxial waveguide 37a toward the planar antenna 31. Then, the microwave is radiated to the space above the wafer W in the processing chamber 1, through the transmitting plate 28, from the slot-shaped microwave radiation holes 32 that are formed to extend through the planar antenna 31.

An electromagnetic field is generated in the processing chamber 1 by the microwave radiated from the planar antenna 31 into the processing chamber 1 through the transmitting plate 28, and a processing gas such as a rare gas, a nitrogen gas, or the like is converted into a plasma. At this time, the microwave is radiated through the microwave radiation holes 32 of the planar antenna 31, thereby generating such a microwave-excited plasma having a high density in a range from approximately 1×10¹⁰ to 5×10¹²/cm³ and a low electron temperature of approximately 1.2 eV or less in the vicinity of the wafer W.

The conditions of the plasma-nitriding process performed in the plasma-nitriding apparatus 100 can be stored as recipes in the storage unit 53 of the control unit 50. The process controller 51 reads out the recipes and transmits control signals to the components, e.g., the gas supply unit 18, the exhaust unit 24, the microwave generator 39, the heater power supply 5a and the like, of the plasma-nitriding apparatus 1, thereby achieving the plasma-nitriding process under the desired conditions.

(Plasma Nitriding Conditions)

Hereinafter, desired conditions for the plasma nitriding process performed by the plasma nitriding apparatus 100 will be described. In the plasma nitriding process of the present embodiment, the flow rate and the flow rate ratio of the processing gas among the following conditions are particularly important in order to efficiently remove the oxygen in the processing chamber 1, to thereby obtain inter-surface uniformity of the nitrogen dose and eliminate causes for generation of particles.

<Processing Gas>

As for a processing gas, it is preferable to use N₂ gas and Ar gas. The flow rate [mL/min(sccm)] of the processing gas containing nitrogen gas and rare gas is controlled in such a way that a total flow rate of the processing gas per volume 1 L of the processing chamber 1 is within the range from about 1.5 (mL/min)/L to 13 (mL/min)/L. Accordingly, oxygen in the processing chamber 1 can be efficiently removed. Further, it is possible to obtain inter-surface uniformity of the nitrogen dose in the plasma nitriding apparatus 100 and eliminate causes for generation of particles.

When the total flow rate of the processing gas is smaller than about 1.5 (mL/min)/L, oxygen is not exhausted from the processing chamber 1. Thus, the components in the processing chamber 1 (particularly, quartz members such as a ceiling plate and the like) are oxidized and peeled by stress during the repetitive processing of the wafer W, which results in generation of particles. When the total flow rate of the processing gas is greater than about 13 (mL/min)/L, it is difficult to exhaust oxygen. Therefore, the quartz members are oxidized, which also results in generation of particles.

The unit [(mL/min)/L] of the total flow denotes the total flow rate [mL/min(sccm)] of the processing gas per volume 1 L of the processing chamber 1. For example, when the volume of the processing chamber 1 is about 55 L, the total flow rate of the processing gas becomes greater than or equal to about 82.5 mL/min(sccm) and smaller than or equal to about 715 mL/min(sccm). In that case, the flow rate of N₂ gas is preferably set within the range from, e.g., about 4.7 mL/min(sccm) to 225 mL/min(sccm). Moreover, the flow rate of Ar gas is preferably set within the range from, e.g., about 95 mL/min(sccm) to 275 mL/min(sccm).

The volume rate ratio of N₂ gas and Ar gas (N₂ gas/Ar gas) contained in the processing gas is set preferably in a range from about 0.05 to 0.8 and more preferably in a range from about 0.2 to 0.8, for example, in view of suppressing oxidation of the components (particularly, quartz members) in the processing chamber 1 by increasing the nitriding power of the plasma, and thus preventing generation of particles.

<Processing Pressure>

In view of increasing the nitriding power of the plasma, the processing pressure is preferably set within a range from about 1.3 Pa to 133 Pa and more preferably within a range from about 1.3 Pa to 53.3 Pa. When the processing pressure is lower than about 1.3 Pa, the base film is damaged. When the processing pressure is higher than about 133 Pa, it is difficult to obtain a sufficient nitriding power. This results in the decrease of the effect in which the generation of particles is prevented by suppressing the oxidation of the quartz members in the processing chamber 1.

<Processing Time>

The processing time is preferably set within a range from, e.g., about 10 sec to 300 sec and more preferably set within the range from about 30 sec to 180 sec. Until a specific period of time, the effect of removing oxygen by a nitrogen-containing plasma is increased as the processing time is increased. The nitrogen-containing plasma is generated under the condition in which a total flow rate [mL/min(sccm)] of the processing gas per volume 1 L of the processing chamber 1 ranges from about 1.5 (mL/min)/L to 13 (mL/min)/L. However, if the processing time is excessively increased, the oxygen-removing effect is no longer increased and the throughput becomes decreased. Therefore, the processing time is preferably set to be as shortly as possible within such a range as to obtain a desired oxygen exhaust effect.

<Power of Microwave>

A power density of a microwave in a plasma nitriding process is set preferably within a range from, e.g., about 0.6 W/cm² to 2.5 W/cm² in view of stably and uniformly generating a nitrogen plasma and reducing particles generated from the quartz members (e.g., the transmitting plat 28) by thermal stress by decreasing the inner temperature of the processing chamber 1. In the present embodiment, the power density of the microwave denotes a microwave power per unit area 1 cm² of the transmitting plate 28.

<Processing Temperature>

The processing temperature (heating temperature of the wafer W), i.e., the temperature of the mounting table 2, is preferably set within a range from, e.g., about 25° C. (about room temperature) to 600° C. and more preferably within a range from about 100° C. to 500° C. in view of reducing particles generated from the quartz members (e.g., the transmitting plate 28) by thermal stress by decreasing the inner temperature of the processing chamber 1. If the processing temperature is decreased, the nitrogen dose is decreased. However, by setting the flow rate of the processing gas as the total flow rate [mL/min(sccm)] of the processing gas per volume 1 L of the processing chamber 1 within a large flow rate range from about 1.5 (mL/min)/L to 13 (mL/min)/L, the decrease in the nitrogen dose caused by the temperature decrease can be suppressed to thereby perform the nitriding process at a high dose.

<Chiller Temperature>

The processing chamber 1 heated to a high temperature by the plasma during the nitriding process is cooled by supplying a heat medium from the chiller unit 26 to the sidewall 1b of the processing chamber 1 and the flow path 34a of the metal cover member 34. The temperature of the processing chamber 1 is preferably set within a range from about 5° C. to 25° C. and more preferably about 10° C. to 15° C., for example, in view of decreasing the particles generated from the surfaces of the quart members (e.g., the transmitting plate 28) by thermal stress by decreasing the inner temperature of the processing chamber 1.

The above-described plasma nitriding conditions may be stored as recipes in the storage unit 53 of the control unit 50. Further, the process controller 51 reads the recipes and transmits control signals to the components, e.g., the gas supply unit 18, the gas exhaust unit 24, the microwave generator 39, the heater power supply 5a and the like, of the plasma nitriding apparatus 100, thereby achieving the plasma nitriding process under the desired conditions.

(Effect)

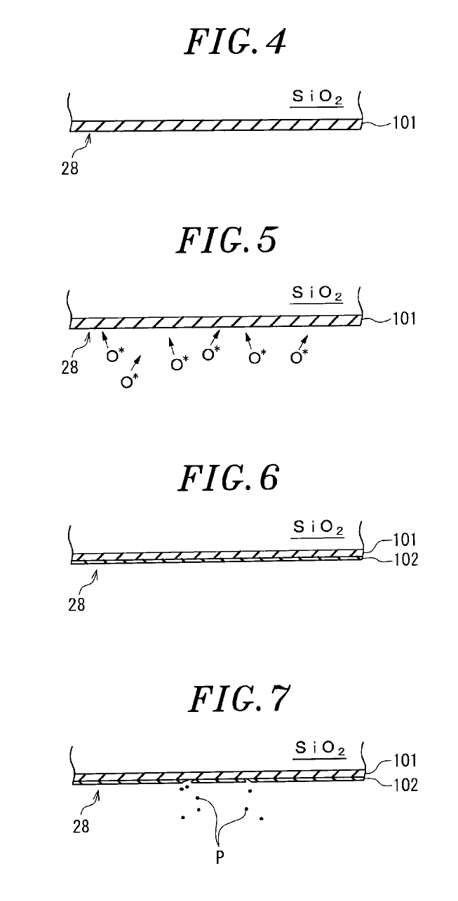

FIGS. 4 to 7 show state changes of the surface of a quartz member (e.g., the transmitting plate 28) when a plasma nitriding process is performed in the processing chamber 1 of the plasma nitriding apparatus 100. When the plasma nitriding process is performed in the processing chamber 1 of the plasma nitriding apparatus 100, the quartz member such as the transmitting plate 28 or the like is exposed to a nitrogen plasma. Therefore, SiO₂ is nitrided and turned into SiON on the surface of the quartz member. As the nitriding is further continued, a thin SiN film 101 is formed on the surface of the quartz member as shown in FIG. 4.

If the plasma nitriding process is continuously performed on a plurality of wafers W each having the state shown in FIG. 4, oxygen in the processing chamber 1 of the plasma nitriding apparatus 100 is excited and becomes atomic oxygen (O*) as shown in FIG. 5, for example. Such atomic oxygen (O*) is diffused into the processing chamber 1, thereby oxidizing the surface of the quartz member such as the transmitting plate 28 or the like. The reason for the increase of the amount of oxygen in the processing chamber 1 is that an oxygen-containing film from which oxygen is easily discharged is formed on the surface of the wafer W as a target object to be processed (e.g., a silicon dioxide film, a metal oxide film, a metal silicon oxide film or the like).

When the oxygen-containing film, e.g., SiO₂ film, is nitrided by a nitrogen plasma, oxygen is substituted by nitrogen, and oxygen atoms (O*) are separated from the oxygen-containing film. The oxygen atoms (O*) are discharged into the processing chamber 1, and this leads to oxidation of the surface of the quartz member. The surface of the quartz member is also oxidized by oxygen introduced from the outside of the processing chamber 1, for example, moisture and the like in the atmosphere which is attached to the wafer W. If the processing time for one wafer W is short, oxygen separated from the wafer W remains in the processing chamber 1 without being exhausted together with the exhaust gas. Therefore, as the number of processed wafers W is increased, oxygen is easily accumulated in the processing chamber 1.

As the oxidation is continued as described above, the surface of the SiN layer 101 formed on the surface of the quartz member such as the transmitting plate 28 or the like in the processing chamber 1 is oxidized, thereby forming a silicon oxynitride layer (SiON layer) 102, as shown in FIG. 6. In other words, SiO₂, SiN and SiON films are formed in the vicinity of the surface of the quartz member from the inside toward the surface side. When the microwave power for plasma excitation is low, the nitriding power is decreased. Therefore, the effect of oxygen is relatively increased, so that the quartz member is easily oxidized by oxygen.

As shown in FIG. 6, while the plasma nitriding process is performed on a plurality of wafers W each having a state where the SiON layer 102 is formed, if the thermal stress is applied thereto, the SiON layer 102 is cracked due to the difference of the thermal expansion coefficient between the SiON layer 102 and the SiN layer 101. As a result, the SiON layer 102 is peeled off as shown in FIG. 7. This is considered as the reason for generation of particles P.

In the plasma nitriding method of the present embodiment, a large amount of processing gas is introduced into the processing chamber 1 in such a way that a total flow rate [mL/min(sccm)] of the processing gas per volume 1 L of the processing chamber 1 ranges from about 1.5 (mL/min)/L to 13 (mL/min)/L and, then, the plasma nitriding process is carried out while performing evacuation by the gas exhaust unit 24. Accordingly, oxygen atoms (oxygen radicals) separated from the wafer W, oxygen ions, or oxygen sources attached to or remaining in the processing chamber 1 can be quickly exhausted to the outside of the processing chamber 1. As a result, even if the plasma nitriding process is repeated in the processing chamber 1, the surface of the quartz member can be constantly maintained in the state shown in FIG. 4 (the state in which the SiN layer 101 is formed).

In other words, by introducing and exhausting a large amount of processing gas, oxygen atoms (oxygen radicals), oxygen ions or oxygen sources in the processing chamber 1 which cause the surface oxidation of the quartz members or the like are exhausted from the processing chamber 1, so that the formation of the SiON layer 102 is suppressed. Thus, the peeling-off caused by thermal stress does not easily occur. Accordingly, as described above, it is possible to prevent the phenomenon in which the surface of the quartz member is peeled off and this causes particles from being generated.

The peeling-off of the SiON layer 102 formed on the quartz member is mainly caused by thermal stress. Thus, the generation of particles can be reliably reduced by decreasing the inner temperature of the processing chamber 1. In this regard, it is preferable to decrease, e.g., the processing temperature (the heating temperature of the wafer W by the heater 5 of the mounting table 2), the power of the microwave generated by the microwave generator 39, and the temperature of the heat medium by the chiller unit 26.

In that case, if the inner temperature of the processing chamber 1 is decreased, the nitriding rate tends to be decreased. However, the extreme decrease of the nitriding rate can be avoided by increasing the flow rate of the processing gas as described above. In other words, the nitriding rate decrease caused by the temperature decrease of the processing chamber 1 can be supplemented by increasing the flow rate of the processing gas.

Moreover, the gas generated from the processed wafer W is easily exhausted from the processing chamber 1 whenever one wafer is completed by introducing the processing gas into the processing chamber 1 at a flow rate that is set as a total flow rate of the processing gas [mL/min(sccm)] per volume 1 L of the processing chamber 1 in a range from about 1.5 (mL/min)/L to 13 (mL/min)/L. Accordingly, a wafer W to be processed next can be prevented from being affected by the gas generated from the previously processed wafer W. As a result, the processing uniformity between wafers W is improved considerably.

Hereinafter, test results in accordance with the embodiment of the present invention will be described.

### Test Example 1

The apparatus having the same configuration as that of the plasma nitriding apparatus 100 shown in FIG. 1 was used to repetitively perform a plasma nitriding process on 25 wafers W under the following low flow rate nitriding conditions 1-A, high flow rate nitriding conditions 1-B and 1-C. A silicon oxide film was formed on a surface of each of the wafers W. For each of the wafers on which the oxide film was formed after the plasma nitriding process, nitrogen doses in the silicon oxide films were measured, and the uniformity of the nitrogen doses among the wafers was examined.

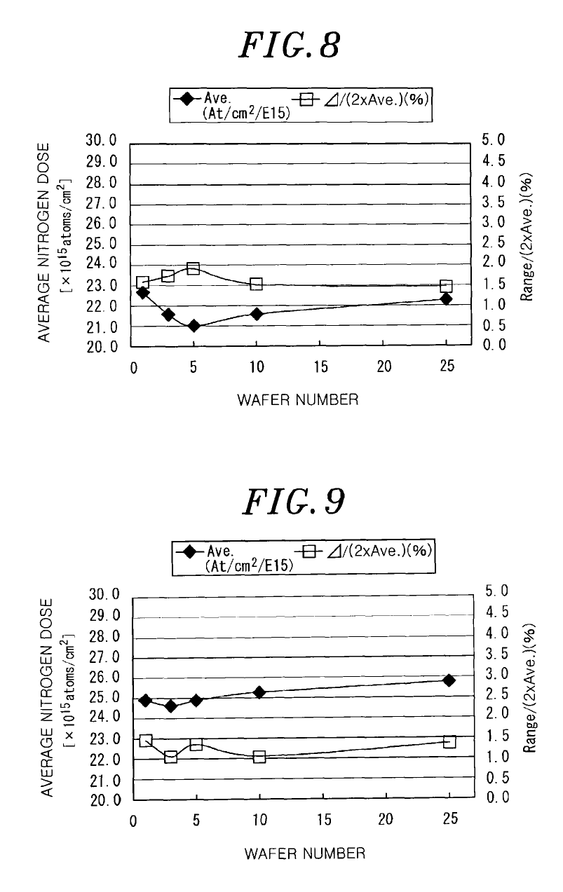

FIGS. 8 to 10 show the results obtained under the low flow rate nitriding conditions 1-A and the high flow rate nitriding conditions 1-B and 1-C, respectively. In FIGS. 8 to 10, the horizontal axis indicates a wafer number; the left vertical axis indicates an average nitrogen dose of nine locations on the corresponding wafer W; and the right vertical axis indicates Range/2Ave.(%) as a uniformity index [i.e., percentage of (maximum nitrogen dose−minimum nitrogen dose)/(2×average nitrogen dose)].

(Nitriding Conditions 1-A)

Processing pressure: 20 Pa

Ar gas flow rate: 60 mL/min(sccm)

N₂ gas flow rate: 20 mL/min(sccm)

Total flow rate: 80 mL/min(sccm)

Frequency of microwave: 2.45 GHz

Power of microwave: 1500 W (power density 0.76 W/cm²)

Processing temperature: 500° C.

Processing time: 90 sec

Wafer diameter: 300 mm

Processing chamber volume: 55 L (low flow rate: 1.45 (mL/min)/L)

(Nitriding Conditions 1-B)

Processing pressure: 20 Pa

Ar gas flow rate: 255 mL/min(sccm)

N₂ gas flow rate: 70 mL/min(sccm)

Total flow rate: 325 mL/min(sccm)

Frequency of microwave: 2.45 GHz

Power of microwave: 1500 W (power density 0.76 W/cm²)

Processing temperature: 500° C.

Processing time: 90 sec

Wafer diameter: 300 mm

Processing chamber volume: 55 L (high flow rate: 5.91 (mL/min)/L)

(Nitriding Conditions 1-C)

Processing pressure: 20 Pa

Ar gas flow rate: 195 mL/min(sccm)

N₂ gas flow rate: 130 mL/min(sccm)

Total flow rate: 325 mL/min(sccm)

Frequency of microwave: 2.45 GHz

Power of microwave: 2000 W (power density 1.01 W/cm²)

Processing temperature: 500° C.

Processing time: 90 sec

Wafer diameter: 300 mm

Processing chamber volume: 55 L (high flow rate: 5.91 (mL/min)/L)

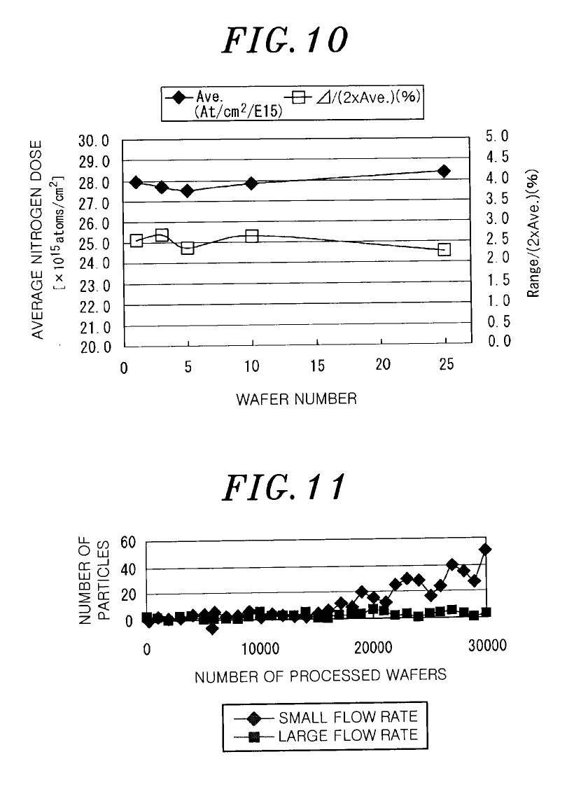

As shown in FIGS. 8 to 10, the average nitrogen dose (plotted by black diamond shapes) is higher in the high flow rate conditions 1-B (FIG. 9) and 1-C (FIG. 10) than in the low flow rate conditions 1-A (FIG. 8). Further, the Range/2Ave. (plotted by white rectangles) among the wafers was about 3.800% in the low flow rate conditions 1-A (FIG. 8), about 2.338% in the high flow rate conditions 1-B and about 1.596% in the high flow rate conditions 1-C (FIG. 10). Besides, it is found that, in the high flow rate conditions 1-B (FIG. 9) and 1-C (FIG. 10), the variation of the nitrogen doses among the wafers is smaller and the inter-wafer processing uniformity is higher. Therefore, it is clear that the inter-wafer uniformity of the nitrogen dose in the plasma nitriding process is higher in the high flow rate conditions 1-B and 1-C than in the low flow rate conditions 1-A.

### Test Example 2

The apparatus having the same configuration as that of the plasma nitriding apparatus 100 shown in FIG. 1 was used to perform a running test for repetitively performing a nitriding process on about 30000 dummy wafers under the following nitriding conditions 2-A and 2-B. A silicon oxide film was formed on a surface of each of the dummy wafers. For the dummy wafers after the plasma nitriding surface, the number of particles was measured by a particle counter. FIG. 11 shows the result thereof. In the nitriding conditions 2-A, the flow rate of the processing gas was relatively small. In the nitriding conditions 2-B, the flow rate of the processing gas was relatively large.

(Nitriding Conditions 2-A)

Processing pressure: 20 Pa

Ar gas flow rate: 48 mL/min(sccm)

N₂ gas flow rate: 32 mL/min(sccm)

Total flow rate: 80 mL/min(sccm)

Frequency of microwave: 2.45 GHz

Power of microwave: 1500 W (power density 0.76 W/cm²)

Processing temperature: 500° C.

Processing time: 90 sec

Wafer diameter: 300 mm

Processing chamber volume: 55 L (low flow rate: 1.45 (mL/min)/L)

(Nitriding Conditions 2-B)

Processing pressure: 20 Pa

Ar gas flow rate: 271 mL/min(sccm)

N₂ gas flow rate: 54 mL/min(sccm)

Total flow rate: 325 mL/min(sccm)

Frequency of microwave: 2.45 GHz

Power of microwave: 1500 W (power density 0.76 W/cm²)

Processing temperature: 500° C.

Processing time: 90 sec

Wafer diameter: 300 mm

Processing chamber volume: 55 L (high flow rate: 5.91 (mL/min)/L)

As shown in FIG. 11, in the low flow rate nitriding conditions 2-A, the number of particles was considerably increased when about 15000 wafers were processed by performing the plasma nitriding process. On the other hand, in the high flow rate nitriding conditions 2-B, the number of particles was hardly increased even after the completion of the processing of about 30000 wafers. This is because, in the high flow rate nitriding conditions 2-B, oxygen generated in the processing chamber is quickly exhausted without remaining in the processing chamber. Therefore, the oxidation of the quartz members and the like is suppressed, and thus a SiON film that causes generation of particles is not easily formed. Accordingly, it is clear that the particles generated in the processing chamber can be efficiently decreased by performing the high flow rate plasma nitriding process.

### Test Example 3

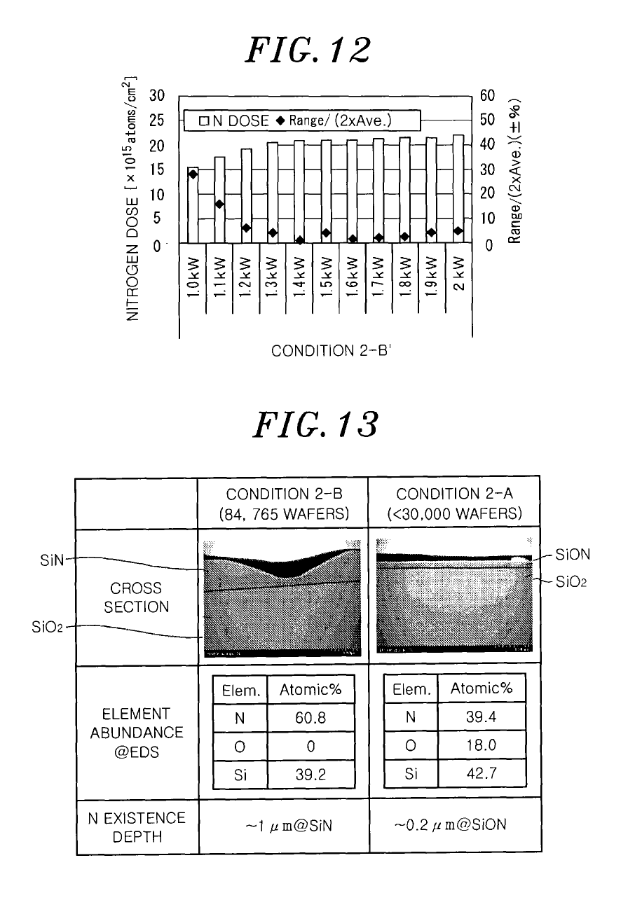

Next, a plasma nitriding process was performed on 25 wafers, each having on a surface thereof a SiO₂ film having a thickness of about 6 mm under the same conditions as those of the conditions 2-B of the test example 2 except that the microwave power was varied in a stepwise manner from about 1000 W (power density per about 1 cm² of the transmitting plate (hereinafter, referred to as “power density”): 0.5 W/cm²) to 2000 W (power density: 1.0 W/cm²) by 100 W. Then, the nitrogen dose in the SiO₂ film and the Range/2Ave.(%) in the wafer surface were examined. FIG. 12 shows the result thereof. When the microwave power was within a range from about 1200 W (power density: 0.6 W/cm²) to 2000 W (power density: 1.0 W/cm²), good inter-wafer uniformity (in-plane uniformity) of the nitrogen dose was obtained.

### Test Example 4

The apparatus having the same configuration as that of the plasma nitriding apparatus 100 shown in FIG. 1 was used to perform a running test for repetitively performing a nitriding process a plurality of wafers, each having on a surface thereof a SiO₂ film, under the same conditions as the conditions 2-A and 2-B of the test example 2. Less than 30000 wafers were processed under the conditions 2-A, and less than 85000 wafers were processed under the conditions 2-B. Thereafter, the cross section near the surface of the transmitting plate 28 was examined by an electron microscope, and the element abundance of that portion was analyzed by an energy dispersive X-ray Spectrometer (EDS). The result thereof is shown in FIG. 13.

As can be seen from FIG. 13, in the low flow rate conditions 2-A, the existence depth of nitrogen measured by the EDS analysis is about 0.2 μm. In this depth range, oxygen is contained. Thus, when the number of processed wafers is smaller than about 30000, a SiON layer is formed on the surface of the transmitting plate 28. This is because the surface of the transmitting plate 28 is oxidized by oxygen discharged from the oxide film when the oxide film is nitrided.

On the other hand, in the high flow rate conditions 2-B, the existence depth of nitrogen measured by the EDS analysis is about 1 μm. In this depth range, oxygen is not contained. Therefore, even after less than 85000 wafers are processed, the SiN layer is maintained. Accordingly, it is clear that, even if the number of processed wafers reaches about 85000, the formation of the SiON layer which causes generation of particles on the surfaces of the quartz members in the processing chamber 1 can be suppressed by performing the plasma nitriding process under the high flow rate conditions 2-B.

As described above, in accordance with the plasma nitriding method of the present embodiment, the processing gas containing nitrogen gas and rare gas is introduced into the processing chamber 1 by setting the flow rate as the total flow rate [mL/min(sccm)] of the processing gas per volume 1 L of the processing chamber 1 within a range from about 1.5 (mL/min)/L to 13 (mL/min)/L. As a consequence, the oxidation of the surfaces of the quartz members in the processing chamber 1 is suppressed, so that the generation of particles in the processing chamber 1 can be efficiently reduced and the processing uniformity of the wafers W can be ensured. Hence, in the plasma nitriding apparatus 100, it is possible to realize the plasma nitriding process in which the generation of particles is suppressed and high reliability is ensured.

The following description relates to a plasma conditioning method as a pre-process which may be performed together with the plasma nitriding method of the present embodiment. The plasma conditioning method serves to perform a conditioning in the processing chamber 1 of the plasma nitriding apparatus 100 in order to reduce particles or contamination (contamination caused by metal atoms, alkali atoms and the like). Conventionally, the plasma conditioning is performed under common conditions when the operation of the plasma nitriding process 100 is started or after the maintenance operation such as disassembly, component exchange or the like is performed. In the conventional plasma conditioning, oxygen plasma and nitrogen plasma are generated in the processing chamber 1.

Such plasma conditioning requires from, e.g., about 13 to 14 hours. Since, however, the plasma conditioning is performed under the same conditions for the same period of time regardless of the state in the processing chamber 1, the operation stop time of the apparatus is increased. In addition, the lifespan of the components (e.g., the transmitting plate 28 and the like) in the processing chamber 1 is decreased due to the long-time irradiation of the plasma.

Therefore, in the present embodiment, the recipes of the plasma conditioning were re-examined, and three-step plasma conditioning recipes (first to third recipes) were prepared in accordance with the state in the processing chamber 1 (particularly, the contamination level). The first recipe is executed when the operation of the plasma nitriding apparatus 100 is started. The second recipe is executed after a relatively large-scale maintenance is performed. Here, the relatively large-scale maintenance includes, e.g., the exchange of the mounting table 2 or the separation of the mounting table 2. The third recipe is executed after a relatively light maintenance operation is performed. Here, the relatively light maintenance includes, e.g., the exchange of the transmitting plate 28, the exchange of the turbo molecular pump of the gas exhaust unit 24, the exchange of the O-ring of the gate valve 17 or the valve body, and the like.

The examples of the contents of the first to the third recipe will be described. The degree of plasma conditioning becomes higher in the order of the first recipe, the second recipe and the third recipe. In accordance with the first recipe, the plasma conditioning is most thoroughly performed under the same contents as those of the conventional plasma conditioning.

[First Recipe]

High pressure oxidation conditioning, low pressure oxidation conditioning, waferless direct conditioning and nitriding conditioning are carried out in that order. The plasma conditioning requires from about 13 to 14 hours. Further, in this specification, the terms “high nitrogen dose” and “low nitrogen dose” are relative expressions for differentiating a pressure difference under the vacuum condition. Hereinafter, the processing conditions of the respective conditionings will be described.

(High Pressure Oxidation Conditioning)

Processing pressure: 400 Pa

Frequency of microwave: 2.45 GHz

Power of microwave: 3800 W (Power density; 1.95 W/cm²)

Ar gas flow rate: 200 mL/min(sccm)

H₂ gas flow rate: 20 mL/min(sccm)

O₂ gas flow rate: 80 mL/min(sccm)

Processing temperature: 500° C.

Processing time·cycle: 60 sec×10 cycles

The number of wafers used: 3 sheets

(Low pressure oxidation conditioning)

Processing pressure: 67 Pa

Frequency of microwave: 2.45 GHz

Power of microwave: 3200 W (Power density; 1.64 W/cm²)

Ar gas flow rate: 200 mL/min(sccm)

H₂ gas flow rate: 20 mL/min(sccm)

O₂ gas flow rate: 80 mL/min(sccm)

Processing temperature: 500° C.

Processing time·cycle: 60 sec×30 cycles

The number of wafers used: 10 sheets

(Waferless Direct Conditioning)

Processing pressure: 67 Pa

Frequency of microwave: 2.45 GHz

Power of microwave: 3200 W (Power density; 1.64 W/cm²)

Ar gas flow rate: 200 mL/min(sccm)

H₂ gas flow rate: 20 mL/min(sccm)

O₂ gas flow rate: 80 mL/min(sccm)

Processing temperature: 500° C.

Processing time·cycle: 60 sec×10 cycles

The number of used wafers: 0

(Nitriding Conditioning)

Processing pressure: 20 Pa

Frequency of microwave: 2.45 GHz

Power of microwave: 2000 W (Power density; 1.0 W/cm²)

Ar gas flow rate: 48 mL/min(sccm)

N₂ gas flow rate: 32 mL/min(sccm)

Processing temperature: 500° C.

Processing time·cycle: 60 sec×10 cycles

The number of wafers used: 5 sheets

[Second Recipe]

Upon completion of the waferless direct conditioning, the high pressure oxidation conditioning and the low pressure oxidation conditioning are alternately repeated. Thereafter, the nitriding conditioning is performed. The plasma conditioning requires from about 7 to 8 hours. The following description relates to processing conditions of the respective conditioning.

(Waferless Direct Conditioning)

Processing pressure: 67 Pa

Frequency of microwave: 2.45 GHz

Power of microwave: 3200 W (Power density; 1.64 W/cm²)

Ar gas flow rate: 200 mL/min(sccm)

H₂ gas flow rate: 20 mL/min(sccm)

O₂ gas flow rate: 80 mL/min(sccm)

Processing temperature: 500° C.

Processing time·cycle: 60 sec×30 cycles

The number of wafers used: 0

(High Pressure Oxidation Conditioning)

Processing pressure: 400 Pa

Frequency of microwave: 2.45 GHz

Power of microwave: 3800 W (Power density; 1.95 W/cm²)

Ar gas flow rate: 200 mL/min(sccm)

H₂ gas flow rate: 20 mL/min(sccm)

O₂ gas flow rate: 80 mL/min(sccm)

Processing temperature: 500° C.

Processing time·cycle: 60 sec×1 cycle

(Low Pressure Oxidation Conditioning)

Processing pressure: 67 Pa

Frequency of microwave: 2.45 GHz

Power of microwave: 3200 W (Power density; 1.64 W/cm²)

Ar gas flow rate: 200 mL/min(sccm)

H₂ gas flow rate: 20 mL/min(sccm)

O₂ gas flow rate: 80 mL/min(sccm)

Processing temperature: 500° C.

Processing time·cycle: 60 sec×1 cycle

The high pressure oxidation conditioning and the low pressure oxidation conditioning are alternately repeated about 30 times by using one wafer.

(Nitriding Conditioning)

Processing pressure: 20 Pa

Frequency of microwave: 2.45 GHz

Power of microwave: 2000 W (Power density; 1.0 W/cm²)

Ar gas flow rate: 48 mL/min(sccm)

H₂ gas flow rate: 32 mL/min(sccm)

Processing temperature: 500° C.

Processing time·cycle: 60 sec×50 cycles

The number of wafers used: 1 sheet

[Third Recipe]

Upon completion of the waferless direct conditioning, the nitriding conditioning is performed. The plasma conditioning requires from about 2 to 3 hours. The following description relates to processing conditions of the respective conditioning.

(Waferless Direct Conditioning)

Processing pressure: 20 Pa

Frequency of microwave: 2.45 GHz

Power of microwave: 2000 W (Power density; 1.0 W/cm²)

Ar gas flow rate: 48 mL/min(sccm)

H₂ gas flow rate: 32 mL/min(sccm)

Processing temperature: 500° C.

Processing time·cycle: 60 sec×30 cycles

The number of wafers used: 0

(Nitriding Conditioning)

Processing pressure: 20 Pa

Frequency of microwave: 2.45 GHz

Power of microwave: 2000 W (Power density; 1.0 W/cm²)

Ar gas flow rate: 48 mL/min(sccm)

N₂ gas flow rate: 32 mL/min(sccm)

Processing temperature: 500° C.

Processing time·cycle: 60 sec×50 cycles

The number of wafers used: 1

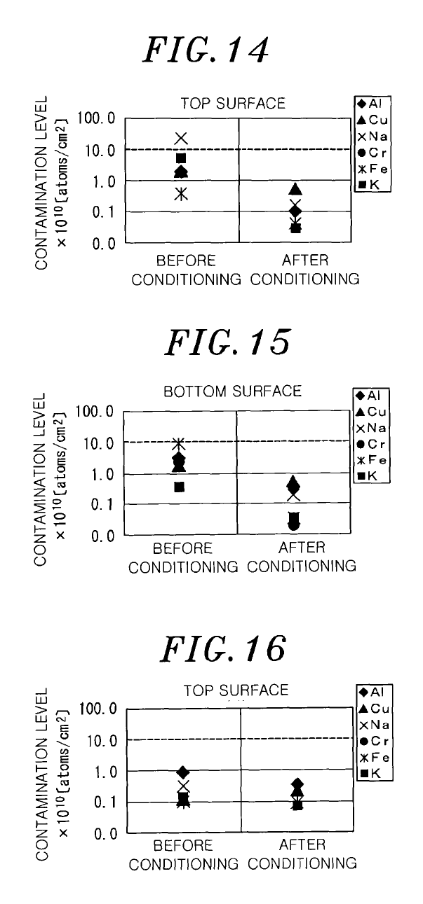

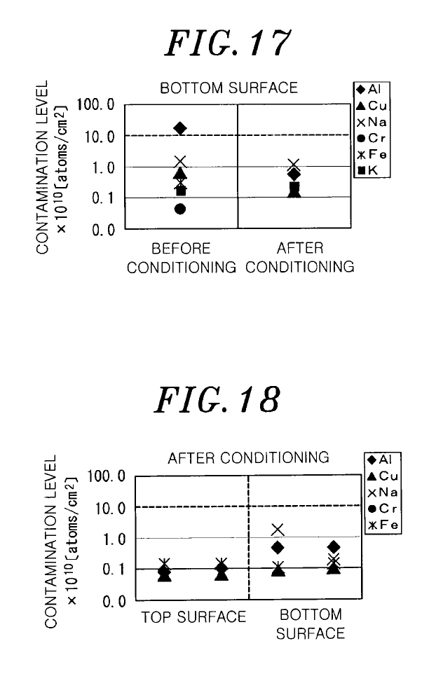

Next, the plasma conditioning was performed based on the first to the third recipe, and the contamination level of the wafer W before and after the plasma conditioning was measured. The contamination level from Al, Cu, Na, Cr, Fe and K was measured. FIGS. 14 and 15 show results in the case of executing the first recipe. FIG. 14 shows a top surface of the wafer W and FIG. 15 shows the contamination level measured on a bottom surface of the wafer W. In the same manner, FIGS. 16 and 17 show results in the case of executing the second recipe. FIG. 16 shows a top surface of the wafer W and FIG. 17 shows the contamination level measured on a bottom surface of the wafer W. FIG. 18 shows the case of executing the third recipe and illustrates the contamination level on the top surface and the bottom surface of the wafer W after the plasma conditioning. In this test, a reference value of the contamination level was set to about 10×10¹⁰ [atoms/cm²].

Referring to FIGS. 14 to 18, when the plasma conditioning was performed based on the second recipe (FIGS. 16 and 17) and the third recipe (FIG. 18), the contamination level of the top surface and the bottom surface of the wafer W was lower than the reference value. In other words, it is clear that when the plasma conditioning was performed based on the second and the third recipe, the contamination level was reduced to the same level as that obtained by the plasma conditioning performed based on the first recipe (FIGS. 14 and 15). On the assumption that the plasma conditioning performed based on the first recipe requires about 100 hours, the plasma conditioning performed based on the second recipe can be shortened to about 41 hours (about ½ or less) and the plasma conditioning performed based on the third recipe can be shorted to about 19 hours (about ⅕).

In other words, the plasma conditioning time can be reduced by selecting any one of the first to the third recipe in accordance with the contamination level in the processing chamber 1. Therefore, the production efficiency can be increased by reducing the operation stop time of the plasma nitriding apparatus 100. Further, the plasma conditioning time is reduced, so that the plasma irradiation time for the consumables in the processing chamber 1 can be decreased. As a result, it is possible to increase the lifespan of the quartz members, e.g., the transmitting plate 28 and the like.

By performing the above plasma conditioning method as the pre-processing method together with the plasma nitriding method of the present embodiment, it is possible to reduce the amount of particles and the contamination. Hence, a semiconductor process in which particle contamination is reliably suppressed can be realized, and the semiconductor device having a high reliability can be provided. Further, the throughput can be improved because the plasma nitriding process is performed after the plasma conditioning in the plasma processing apparatus.

While the invention has been shown and described with respect to the embodiments, it will be understood by those skilled in the art that various changes and modifications may be made without departing from the scope of the invention as defined in the following claims. For example, in the above-described embodiment, the RLSA-type plasma-nitriding apparatus 100 is used. However, it is also possible to use a plasma processing apparatus of another type, e.g., a parallel plate type, an electron cyclotron resonance (ECR) plasma type, a magnetron plasma type, a surface wave plasma (SWP) type or the like.

In the above embodiment, a plasma nitriding process using a semiconductor wafer as a target object to be processed has been described as an example. However, a substrate as the target object may be, e.g., a substrate for a FPD (Flat Panel Display), a substrate for a solar cell, or the like.

This application claims priority to Japanese Patent Application No. 2010-81985 filed on Mar. 31, 2010, the entire contents of which are incorporated herein by reference.

What is claimed is:

1. A plasma nitriding method comprising:
introducing a processing gas containing nitrogen gas and rare gas into a processing chamber of a plasma processing apparatus by setting a flow rate thereof as a total flow rate [mL/min(sccm)] of the processing gas per 1 L volume of the processing chamber within a range from 1.5 (mL/min)/L to 13 (mL/min)/L; and
performing a nitriding process on oxygen-containing films of target objects to be processed by generating a nitrogen-containing plasma in the processing chamber and while exchanging the target objects.

2. The plasma nitriding method of claim 1, wherein a volume flow rate ratio (nitrogen gas/rare gas) of the nitrogen gas and the rare gas is set within a range from about 0.05 to 0.8.

3. The plasma nitriding method of claim 2, wherein the flow rate of the nitrogen gas is set within a range from about 4.7 mL/min(sccm) to 225 mL/min(sccm), and the flow rate of the rare gas is set within a range from about 95 mL/min(sccm) to 275 mL/min (sccm).

4. The plasma nitriding method of claim 1, wherein a pressure in the processing chamber is set within a range from about 1.3 Pa to 133 Pa.

5. The plasma nitriding method of claim 1, wherein a processing time for one target object in the plasma nitriding process is set within a range from about 10 sec to 300 sec.

6. The plasma nitriding method of claim 1, wherein the plasma processing apparatus includes:
the processing chamber having an upper opening;
a mounting table, provided in the processing chamber, for mounting thereon the target object;
a transmitting plate provided to face the mounting table, the transmitting plate covering the opening of the processing chamber and transmitting a microwave;
a planar antenna provided outside the transmitting plate, the planar antenna having a plurality of slots through which the microwave is introduced into the processing chamber;
a gas inlet for introducing the processing gas containing nitrogen gas and rare gas from a gas supply unit into the processing chamber; and
a gas exhaust unit for vacuum-evacuating the processing chamber,
wherein the nitrogen plasma is a microwave-excited plasma formed by the processing gas and a microwave introduced into the processing chamber through the planar antenna.

7. The plasma nitriding method of claim 6, wherein a power density of the microwave is set in a range from about 0.6 W/cm² to 2.5 W/cm² per area of the transmitting plate.

8. The plasma nitriding method of claim 6, wherein the processing temperature is a temperature of the mounting table and is set within a range from about 25° C. (room temperature) to about 600° C.

9. A plasma nitriding apparatus comprising:
a processing chamber having an upper opening;
a mounting table, provided in the processing chamber, for mounting thereon a target object to be processed;
a transmitting plate provided to face the mounting table, the transmitting plate covering the opening of the processing chamber and transmitting a microwave;
a planar antenna, provided outside the transmitting plate, the planar antenna having a plurality of slots through which the microwave is introduced into the processing chamber;
a gas inlet for introducing a processing gas containing nitrogen gas and rare gas from a gas supply unit into the processing chamber;
a gas exhaust unit for vacuum-evacuating the processing chamber; and
a control unit for controlling a plasma nitriding process to be performed on the target object in the processing chamber,
wherein the control unit performs the steps of:
lowering a pressure in the processing chamber to a predetermined level by exhausting the processing chamber by the gas exhaust unit;
introducing the processing gas containing nitrogen gas and rare gas from the gas supply unit into the processing chamber through the gas inlet by setting a flow rate thereof as a total flow rate [mL/min(sccm)] of the processing gas per 1 L volume of the processing chamber within a range from 1.5 (mL/min)/L to 13 (mL/min)/L;
generating a nitrogen-containing plasma in the processing chamber by introducing the microwave into the processing chamber through the planar antenna and the transmitting plate; and
nitriding an oxygen-containing film of the target object by using the nitrogen-containing plasma.
